(19) United States
(12) Patent Application Publication
(10) Pub. No.: US 2013/0200403 A1
(43) Pub. Date: Aug. 8, 2013

(54) PACKAGE STRUCTURE FOR SEMICONDUCTOR LIGHT EMITTING DEVICE

(71) Applicant: Lextar Electronics Corporation, Hsinchu (TW)

(72) Inventors: Ming-Huang Chen, Kaohsiung City (TW); Hui-Kai Hsu, Taitung City (TW)

(73) Assignee: Lextar Electronics Corporation, Hsinchu (TW)

(21) Appl. No.: 13/757,885

(22) Filed: Feb. 4, 2013

(30) Foreign Application Priority Data
Feb. 8, 2012 (TW) 101104120

(51) Int. Cl. H01L 33/62; H01L 33/52

(52) U.S. Cl. CPC H01L 33/62; H01L 33/52
USPC 257/88; 257/99

(57) ABSTRACT

A package structure for a semiconductor light emitting device is provided. The package structure includes a semiconductor light emitting device, a lead frame, an electrostatic discharge protection device and an encapsulation. The lead frame supports the semiconductor light emitting device, and has a gap. The electrostatic discharge protection device is fastened in the gap and electrically connected to the lead frame. The encapsulation covers the lead frame, the semiconductor light emitting device and the electrostatic discharge protection device.

This application claims the benefit of Taiwan application Serial No. 101104120, filed Feb. 8, 2012, the subject matter of which is incorporated herein by reference.

### BACKGROUND OF THE INVENTION

1. Field of the Invention

The invention relates in general to a package structure, and more particularly to a package structure for the semiconductor light emitting device.

2. Description of the Related Art

Light emitting diode (LED) is a commonly used semiconductor light emitting device, and has been widely used in monitors, illumination devices, large-sized display panels, traffic lights and vehicles and become a new generation power saving light source due to the features of long lifespan, low power consumption and high energy utilization rate.

However, the package structure of the light emitting diode may easily be damaged due to electrostatic discharge (ESD). Therefore, the protection against electrostatic discharge is very important to the light emitting diode. Particularly, without affecting the light extraction efficiency of the package structure of the light emitting diode, how to equip the light emitting diode with an electrostatic discharge protection device which does not easily absorb or block the light emitted by the light emitting diode has become a prominent task for the industries.

### SUMMARY OF THE INVENTION

The invention is directed to a package structure for the semiconductor light emitting device capable of avoiding the semiconductor light emitting device being affected by electrostatic discharge and further increasing the light extraction efficiency of the package structure for the semiconductor light emitting device under the circumstances that the wire bonding process is not required for the electrostatic discharge protection device and the amount of the light absorbed by the electrostatic discharge protection device is reduced.

According to an embodiment of the present invention, a package structure for a semiconductor light emitting device is provided. The package structure includes a semiconductor light emitting device, a lead frame, an electrostatic discharge protection device and an encapsulation. The lead frame supports the semiconductor light emitting device, and has a gap. The electrostatic discharge protection device is fastened in the gap and electrically connected to the lead frame. The encapsulation covers the lead frame, the semiconductor light emitting device and the electrostatic discharge protection device.

According to another embodiment of the present invention, a package structure for a semiconductor light emitting device is provided. The package structure includes a semiconductor light emitting device, a lead frame, an electrostatic discharge protection device and an encapsulation. The lead frame supports the semiconductor light emitting device. The lead frame includes an anode lead frame and a cathode lead frame. The electrostatic discharge protection device is disposed between the anode lead frame and the cathode lead frame and electrically connected to the anode lead frame and the cathode lead frame. The encapsulation covers the lead frame, the semiconductor light emitting device and the electrostatic discharge protection device.

According to an alternate embodiment of the present invention, a package structure for semiconductor light emitting device is provided. The package structure includes several semiconductor light emitting devices, a lead frame, several electrostatic discharge protection devices and an encapsulation. The lead frame has several supporting bases respectively supporting the semiconductor light emitting devices. The lead frame has several gaps each being disposed between two neighboring supporting bases. The electrostatic discharge protection devices are respectively fastened in the gaps and electrically connected to the lead frame. The encapsulation covers the lead frame, the semiconductor light emitting devices and the electrostatic discharge protection devices.

The above and other aspects of the invention will become better understood with regard to the following detailed description of the preferred but non-limiting embodiments. The following description is made with reference to the accompanying drawings.

### BRIEF DESCRIPTION OF THE DRAWINGS

FIG. 1 shows a cross-sectional view of a package structure for the semiconductor light emitting device according to an embodiment of the invention; and

FIG. 2 shows a cross-sectional view of a package structure for the semiconductor light emitting device according to another embodiment of the invention.

### DETAILED DESCRIPTION OF THE INVENTION

A package structure for the semiconductor light emitting device is provided in the present embodiment of the invention. The electrostatic discharge protection device is embedded in a gap formed in the lead frame or is embedded between two lead frames. The electrostatic discharge protection device is further fastened by a conductive adhesive (such as silver colloid), such that the electrostatic discharge protection device and the lead frame are electrically connected. Since the electrostatic discharge protection device being an embedded element does not require wire bonding process nor absorb or block the light emitted by the semiconductor light emitting device, the light extraction efficiency of the package structure for the semiconductor light emitting device is thus increased.

A number of embodiments are disclosed below for elaborating the invention. However, the embodiments below are for elaboration purpose only, not for limiting the scope of protection of the invention.

### First Embodiment

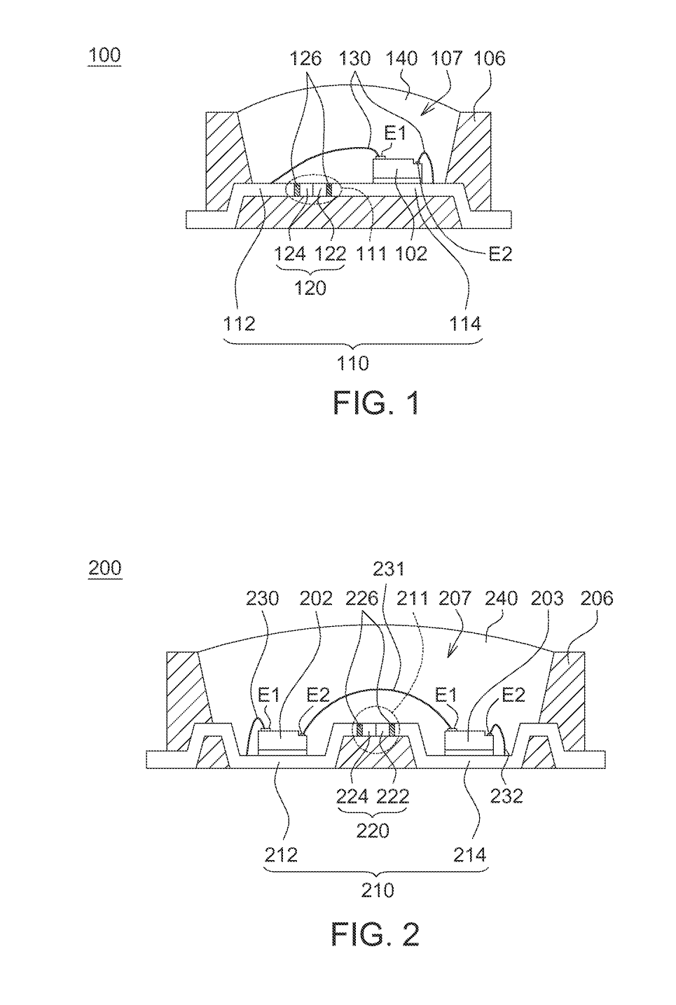

Referring to FIG. 1, a cross-sectional view of a package structure for semiconductor light emitting device according to an embodiment of the invention is shown. The package structure 100 includes a semiconductor light emitting device 102, a lead frame 110, an electrostatic discharge protection device 120, several wires 130 and an encapsulation 140. The encapsulation 140, such as a transparent encapsulation, is interposed in an opening 107 formed by a cup-shaped package casing 106 and covers the lead frame 110, the semiconductor light emitting device 102, the electrostatic discharge protection device 120 and several wires 130 which are disposed in the opening 107. However, the invention is not limited to the above exemplification, and the encapsulation 140 may directly cover the lead frame 110 lacking the package casing 106.

As indicated in FIG. 1, the lead frame 110 supports the semiconductor light emitting device 102, and has a gap 111. The electrostatic discharge protection device 120 is fastened in the gap 111 by the conductive adhesive 126 and electrically connected to the lead frame 110. Besides, the wires 130, such as gold wires, are electrically connected between the semiconductor light emitting device 102 and the lead frame 110 by the wire bonding process and transmit electrical signals to the semiconductor light emitting device 102 for enabling the semiconductor light emitting device 102 to illuminate. The invention is not limited to wire bonding type semiconductor light emitting device 102, and flip-chip type semiconductor light emitting device which is electrically connected to the lead frame 110 through a conductive bump (not illustrated) would also do.

In the present embodiment, the semiconductor light emitting device 102, which may be a light emitting diode, includes a P-type semiconductor layer, an active layer and an N-type semiconductor layer (all are not illustrated). The active layer is disposed between the P-type semiconductor layer and the N-type semiconductor layer to form a PN joint. A P-type electrode E1 and an N-type electrode E2 are disposed above the P-type semiconductor layer and the N-type semiconductor layer, respectively. When a voltage is applied on the P-type electrode E1 and the N-type electrode E2 of the semiconductor light emitting device 102, the electrons and the holes are integrated in the active layer and then are emitted in the form of light.

Besides, the electrostatic discharge protection device 120 may be a Zener diode. Referring to FIG. 1, the electrostatic discharge protection device 120 includes a P-type semiconductor layer 122 and an N-type semiconductor layer 124. The electrostatic discharge protection device 120 is disposed between the anode lead frame 112 and the cathode lead frame 114, wherein the N-type semiconductor layer 124 contacts the anode lead frame 112, and the P-type semiconductor layer 122 contacts the cathode lead frame 114. To avoid the semiconductor light emitting device 102 being damaged by electrostatic discharge, the semiconductor light emitting device 102 and the electrostatic discharge protection device 120 are electrically connected to each other in reverse parallel. That is, the P-type semiconductor layer of the semiconductor light emitting device 102 is connected to the N-type semiconductor layer 124 of the electrostatic discharge protection device 120, and the N-type semiconductor layer of the semiconductor light emitting device 102 is connected to the P-type semiconductor layer 122 of the electrostatic discharge protection device 120. Under normal circumstances, when a forwarding working voltage is inputted, the input voltage only conducts the semiconductor light emitting device 102 to illuminate, and will not flow through the electrostatic discharge protection device 120 (Zener diode). When electrostatic discharge occurs, a tremendous input voltage will be generated and make the electrostatic discharge protection device 120 (Zener diode) collapse. Consequently, most currents will flow through the electrostatic discharge protection device 120 (Zener diode) instead of the semiconductor light emitting device 102, hence avoiding the semiconductor light emitting device 102 being damaged by electrostatic discharge.

In the present embodiment, the two ends of the electrostatic discharge protection device 120 are respectively fastened in the gap 111 or between the anode lead frame 112 and the cathode lead frame 114 by the conductive adhesive 126 without using conventional wire bonding process, and the efficiency of the manufacturing process can thus be increased. Besides, the light emitted by the semiconductor light emitting device 102 will not be absorbed or blocked by the electrostatic discharge protection device 120. In other words, the light extraction efficiency of the package structure 100 for the semiconductor light emitting device is relatively increased.

### Second Embodiment

Referring to FIG. 2, a cross-sectional view of a package structure for semiconductor light emitting device according to another embodiment of the invention is shown. The package structure 200 includes two semiconductor light emitting devices 202 and 203, a lead frame 210, an electrostatic discharge protection device 220, several wires 230 and an encapsulation 240. The encapsulation 240 is interposed to an opening 207 formed by a cup-shaped package casing 206 and covers the lead frame 210, the semiconductor light emitting devices 202 and 203, the electrostatic discharge protection device 220 and several wires 230 which are disposed in the opening 207. The present embodiment is different from the first embodiment in that the lead frame 210 has a first supporting base 212 and a second supporting base 214, which support the first semiconductor light emitting device 202 and the second semiconductor light emitting device 203 respectively. Besides, the lead frame 210 has a gap 211 disposed between the first supporting base 212 and the second supporting base 214, and the electrostatic discharge protection device 220 fastened in the gap 211 by the conductive adhesive 226 is electrically connected to the first supporting base 212 and the second supporting base 214 by the N-type semiconductor layer 224 and the P-type semiconductor layer 222 respectively.

As indicated in FIG. 2, the N-type electrode E2 of the semiconductor light emitting device 202 is serially connected to the P-type electrode E1 of the semiconductor light emitting device 203 through the wire 231, and the P-type electrode E1 of the semiconductor light emitting device 202 is electrically connected to the first supporting base 212 through the wire 230. Besides, the N-type electrode E2 of the semiconductor light emitting device 203 is electrically connected to the second supporting base 214 through the wire 232. Since the electrostatic discharge protection device 220 is disposed between the first supporting base 212 and the second supporting base 214, and two semiconductor light emitting devices 202 and 203 and the electrostatic discharge protection device 220 are electrically connected to each other in reverse parallel, the two semiconductor light emitting devices 202 and 203 will not be damaged by electrostatic discharge.

FIG. 2 of the present embodiment only illustrates one gap and two supporting bases. However, anyone who is skilled in the art will understand that when the lead frame 210 has N gaps 211 and N+1 supporting bases (N is a positive integral greater than or equal to 2), each gap 211 is disposed between two neighboring supporting bases, and N electrostatic discharge protection devices are respectively fastened in N gaps 211 to avoid the semiconductor light emitting devices being damaged by electrostatic discharge.

In the present embodiment, the semiconductor light emitting device 202 and 203 may be light emitting diodes, and the electrostatic discharge protection device 220 may be a component such as Zener diode. Under normal circumstances, when a forwarding working voltage is inputted, the input voltage only conduct the semiconductor light emitting devices 202 and 203 to illuminate, and will not flow through the electrostatic discharge protection device 220 (Zener diode). When electrostatic discharge occurs, a tremendous input voltage will be generated and make the electrostatic discharge protection device 220 (Zener diode) collapse. Consequently, most currents will flow through the electrostatic discharge protection device 220 (Zener diode) instead of the semiconductor light emitting devices 202 and 203, hence avoiding the semiconductor light emitting devices 202 and 203 being damaged by electrostatic discharge.

In the present embodiment, two ends of the electrostatic discharge protection device 220 are respectively fastened in the gap 211 or between the anode lead frame 212 and the cathode lead frame 214 by the conductive adhesive 226 without using conventional wire bonding process, and the efficiency of the manufacturing process can thus be increased. Besides, the light emitted by the semiconductor light emitting devices 202 and 203 will not be absorbed or blocked by the electrostatic discharge protection device 220. In other words, the light extraction efficiency of the package structure 200 for the semiconductor light emitting device is relatively increased.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A package structure for a semiconductor light emitting device, comprising:
a semiconductor light emitting device;
a lead frame supporting the semiconductor light emitting device, wherein the lead frame has a gap;
an electrostatic discharge protection device fastened in the gap and electrically connected to the lead frame; and
an encapsulation covering the lead frame, the semiconductor light emitting device and the electrostatic discharge protection device.

2. The package structure for the semiconductor light emitting device according to claim 1, further comprising a plurality of wires through which the semiconductor light emitting device and the lead frame are electrically connected.

3. The package structure for the semiconductor light emitting device according to claim 1, wherein the semiconductor light emitting device is a light emitting diode.

4. The package structure for the semiconductor light emitting device according to claim 1, wherein the electrostatic discharge protection device is a Zener diode.

5. The package structure for the semiconductor light emitting device according to claim 1, wherein the electrostatic discharge protection device is fastened in the gap by a conductive adhesive.

6. A package structure for a semiconductor light emitting device, comprising:
a semiconductor light emitting device;
a lead frame supporting the semiconductor light emitting device and comprising an anode lead frame and a cathode lead frame;
an electrostatic discharge protection device disposed between the anode lead frame and the cathode lead frame and electrically connected to the anode lead frame and the cathode lead frame; and
an encapsulation covering the lead frame, the semiconductor light emitting device and the electrostatic discharge protection device.

7. The package structure for the semiconductor light emitting device according to claim 6, wherein the electrostatic discharge protection device comprising a P-type semiconductor layer and an N-type semiconductor layer, the P-type semiconductor layer contacts the cathode lead frame, and the N-type semiconductor layer contacts the anode lead frame.

8. The package structure for the semiconductor light emitting device according to claim 6, further comprising a plurality of wires through which the semiconductor light emitting device and the lead frame are electrically connected.

9. The package structure for the semiconductor light emitting device according to claim 6, wherein the semiconductor light emitting device a light emitting diode.

10. The package structure for the semiconductor light emitting device according to claim 6, wherein the electrostatic discharge protection device is a Zener diode.

11. The package structure for the semiconductor light emitting device according to claim 6, wherein the electrostatic discharge protection device is fastened between the anode lead frame and the cathode lead frame by a conductive adhesive.

12. A package structure for a semiconductor light emitting device, comprising:
a plurality of semiconductor light emitting devices;
a lead frame having a plurality of supporting bases respectively supporting the semiconductor light emitting devices, wherein the lead frame has a plurality of gaps, each gap being disposed between two neighboring supporting bases;
a plurality of electrostatic discharge protection devices respectively fastened in the gaps and electrically connected to the lead frame; and
an encapsulation covering the lead frame, the semiconductor light emitting devices and the electrostatic discharge protection devices.

13. The package structure for the semiconductor light emitting device according to claim 12, further comprising a plurality of wires through which the semiconductor light emitting devices and the lead frame are electrically connected.

14. The package structure for the semiconductor light emitting device according to claim 12, wherein the semiconductor light emitting devices are light emitting diodes.

15. The package structure for the semiconductor light emitting device according to claim 12, wherein the electrostatic discharge protection devices are Zener diodes.

16. The package structure for the semiconductor light emitting device according to claim 12, wherein the electrostatic discharge protection devices are fastened in the gaps by a conductive adhesive respectively.
